(19) United States
(12) Patent Application Publication
(10) Pub. No.: US 2009/0305484 A1
(43) Pub. Date: Dec. 10, 2009

(54) METHOD AND REACTOR FOR GROWING CRYSTALS

(76) Inventor: Maurizo Masi, Milano (IT)

Correspondence Address: GARY F. WITTING, 5834 EAST OAK STREET, SCOTTSDALE, AZ, 85257, US

(21) Appl. No.: 11/995,314

(22) PCT Filed: Jul. 10, 2006
(86) PCT No.: PCT/EP06/06723

§ 371 Date: Jun. 10, 2009

(30) Foreign Application Priority Data
Jul. 11, 2005 (IT) MI2005A001308

(51) Int. Cl. H01L 21/365; C23C 16/448

(52) U.S. Cl. 438/478; 118/724; 257/E21.463

(57) ABSTRACT

The reactor for growing crystals on substrates comprises a reaction chamber, support for at least one seed, inlet means for at least one reaction gas, inlet for combustion gasses and means for triggering combustion between said combustion gasses. The growth of a crystal on a seed located inside the reaction chamber comprises the steps of introducing at least one reaction gas into the reaction chamber, introducing combustion gasses into the reaction chamber, triggering combustion between the combustion gasses and depositing the material so generated on the seed.

The present invention relates to a method and a reactor for growing crystals.

The present invention finds application particularly in the growth of silicon carbide crystals but also of other semiconductor materials such as in particular gallium nitride, aluminum nitride, gallium arsenide, indium arsenide, gallium phosphite, indium phoshite and also silicon.

For the development of microelectronic and optoelectronic applications, it is important to have large, high-quality wafers available. Usually these wafers are obtained by cutting single-crystal ingots (simply stated “crystals”) grown by using special processes.

For instance, a silicon or gallium arsenide crystal may be relatively quickly grown from the melted phase by means of a Czochralski pulling process. Unfortunately, this kind of processes is practically not available for many other semiconductor materials such as silicon carbide [SiC] and gallium nitride [GaN] and aluminum nitride [AlN].

At present some growth techniques exist which are suitable for producing crystals of SiC and other semiconductor materials.

The most common known method is sublimation, also designated by the acronym PVT [Physical Vapor Transport].

Another known method is chemical deposition from the vapour phase at high temperature, designated by the acronym HTCVD [High Temperature Chemical Vapour Deposition].

Both of these methods are implemented in “hot-wall” machines, wherein the energy required for the reaction is provided by an external source, typically through resistance or induction heating. It follows that the walls of the reaction chamber are the hottest point of the growth system. Typically, these walls are made of graphite or coated graphite to withstand the extremely aggressive conditions arising during these processes (in terms of both temperature and chemical aggressiveness). This often leads to an “active” behaviour of the walls themselves, since they may incorporate and release chemical species during the growth processes. The walls and the heating thereof are critical aspects as regards the control of the electric characteristics of the growing crystal.

In view of an industrial use, the above-mentioned methods for growing silicon carbide crystals available today are not therefore fully satisfactory in terms of quantity (low productivity), size (small diameters and low lengths) and quality (high density of crystallographic defects).

The object of the present invention is to overcome the drawbacks of the prior art.

Said object is achieved through the method and reactor for growing crystals of semiconductor materials on a seed incorporating the features set out in the annexed claims, which are to be considered as an integral part of the present description.

The general idea at the basis of the present invention is to generate the heat required for the reaction inside the reaction chamber.

Advantageously, said heat is generated by combustion.

For the sake of completeness, it is worth noting that from U.S. Pat. No. 5,652,021 there is known a so-called CCVD [Combustion Chemical Vapour Deposition] method of applying a coating of a metal or a metallic compound, in particular a metal oxide, to a substrate. According to this method, the heat necessary for the CVD process derives from a combustion.

The key to this invention is the direct combustion of flammable liquids or vapours which contain the elements, or reagents, to be deposited on the substrate; organic solvents are sprayed or atomized and burned in an oxidizing gas, i.e. oxygen and/or air; it is also considered to add a fuel, such as hydrogen or ammonia, to the solvent-reagent solution.

It is to be noted that the presence of oxygen during the growth of semiconductor materials leads to either unwanted compounds or defects in the material grown.

Therefore, according to the present invention, the combustion is preferably obtained directly in the reaction chamber but using a flame compatible with the growth process (especially with the reagents, i.e. the reaction gasses, and the resulting semiconductor material grown), in particular both before the combustion, i.e. in terms of fuel and oxidant (combustion gasses), and after the combustion, i.e. in terms of combustion products.

The present invention will become more apparent from the following description and from the annexed drawings, wherein:

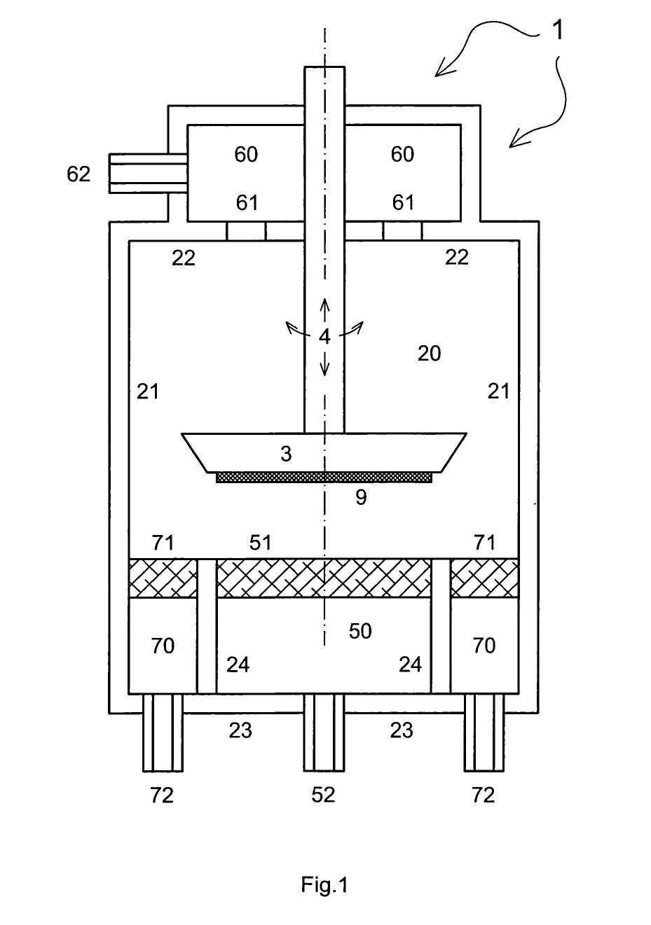

FIG. 1 is a very schematic sectional view of a reactor according to the present invention,

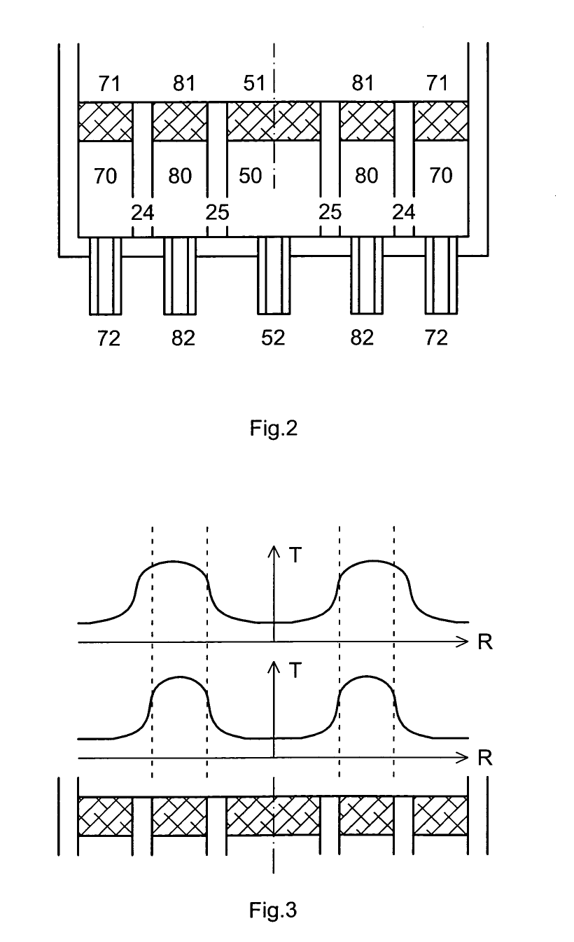

FIG. 2 is a very schematic sectional view of a burner which may be used for the present invention, and

FIG. 3 generally shows the temperature profile above the top surface of the burner of FIG. 2 at two different distances.

Said description and said drawings are to be considered as explanatory non-limiting examples of the present invention. The following description will refer mainly to the growth of silicon carbide crystals.

The preferred growth method according to the present invention involves an autothermal reaction condition, i.e. the heat necessary to reach the process temperatures is generated by a chemical reaction inside the reactor itself. Thus it is possible to create a reactor with a reaction chamber being conceptually without walls (of course, the walls are necessary for its practical realization, but they are not a critical factor of the reactor project).

Advantageously, said heat is generated by combustion directly inside the reaction chamber; in this case, it is necessary to find a flame compatible with the material to be grown and with the reagents used for said growth.

In a flame compatible with the growth of e.g. silicon carbide, the fuel is hydrogen and the oxidant is chlorine. These elements determine the following highly exothermal combustion reaction: H₂+Cl₂→2 HCl.

The adiabatic temperature rise of this flame reaches and exceeds 3,000° C.; said temperature can be modulated down by adding inert gasses, such as helium or argon, or a stoichiometric excess of hydrogen.

The reaction is extremely fast, like any combustion reaction, and is therefore capable of providing all the heat required by the process for decomposing the precursors of the semiconductor material to be grown.

For a H/Cl flame, hydrochloric acid [HCl] is provided as a flame product. Hydrochloric acid has a beneficial effect e.g. in a SiC growth process, since it notoriously avoids/prevents the formation of particulate (in particular liquid drops of Si and/or solid particles of SiC) due to the formation of a stable radical intermediate, like SiCl₂.

It follows that, unlike all known growth processes, the one described herein can be conducted in autothermal way. The flame can be restricted, i.e. confined, by admitting an inert gas which laps the reactor walls and encloses the flame itself. By so doing, the walls can be kept at a temperature being much lower than the process temperature, so that they may even be made of materials being more inert than those currently used in PVT and HTCVD reactors; for example, the walls may be made of quartz or even metal, in particular stainless steel.

Therefore, the process described herein is capable of creating conditions wherein the walls are not actively involved in the process, since theoretically they might be realized through an appropriate gas flow.

Thus, the present invention proposes a semiconductor material growth process wherein the deposition precursors are supplied within or beside (and preferably in parallel to) a suitable support flame. The necessary process temperatures are ensured by the flame adiabatic temperature rise (ratio between the heat generated by the reaction and the specific heat of the gasses removing it), whereas the distribution of the gasses and the radial and axial temperature profiles are determined by the burner design. Depending on the process taken into account, one may provide either laminar or turbulent flames as well as premixed or diffusive flames (in principle there are four possibilities even if typically a laminar flame is premixed and a turbulent flame is diffusive).

According to a first configuration (FIG. 1 below), a premixed laminar flame is used which ensures a good radial uniformity in terms of both composition and temperature. The distribution of the gasses is achieved through a mixing chamber (50) surmounted by a porous element (51) which ensures a radially uniform distribution of the gasses inside (20) the reaction chamber (2). The porous element is preferably provided with a cooling system (not shown in FIG. 1) which may be used for controlling the temperature both in the porous element (51 and possibly 71) and in the mixing chamber (50), so as to prevent the gasses from pre-reacting inside the chamber (50) and/or the porous element (51).

According to a second configuration (FIG. 2), the laminar flame is subdivided between two coaxial distributors, both of which employing porous elements. Reaction gasses, i.e. growth precursors and possibly at least one carrier gas, are supplied into the central part (50). Combustion gasses, i.e. flame reagents and possibly a dilution gas, are supplied into the annular area (80). It is also possible to mix reaction gasses and combustion gasses in the central part (50) in order to obtain a temperature modulation effect. In this case as well, one may advantageously provide a cooling system for either or both porous elements (51, 81). The distribution of temperature inside (20) the reaction chamber (2) obtained through this second configuration aims at providing a so-called “thermal lens” which focuses the growth precursors toward the centre of the reaction chamber and the carrier gasses toward the walls of the reaction chamber because of thermodiffusion or thermophoretic force; this is easily understood with the help of FIG. 3, which generally shows the temperature profile above the top surface of the burner of FIG. 2, i.e. above its porous elements (51, 81), at two different distances (the upper graph refers to a higher level). This ensures an increase in the growth rate and in the efficiency of the reagents used, because deposition on the “cold” walls of the reaction chamber is eliminated or at least reduced.

A system reaching such high temperatures (e.g. 3,000° C.) preferably requires a thermal shielding in order to provide a flame being as adiabatic as possible. The reactor walls, in particular the side walls (21), will thus advantageously be capable of providing reflection of radiant energy, since heat losses are substantially due to irradiation. For this purpose, one may think of using “golden” quartz or quartz coated with a reflecting coating. Moreover, the reactor walls, in particular the side walls (21), may be cooled externally by air or water in order to be kept at temperatures compatible with the material they are made of, e.g. quartz or stainless steel. Thus the restrictions imposed by graphite (either coated or not) will be overcome.

Being an epitaxial-type growth process, the process described herein may also be employed for growing layers, but given the high growth rate it is particularly suited to growing crystals.

### DESCRIPTION OF THE REACTOR

FIG. 1 is a very schematic sectional view of a reactor according to the present invention.

The reference numeral 1 designates the reactor as a whole. The reference numeral 2 designates the reaction chamber as a whole, which is cylindrical in shape; it is provided with an inner space 20 wherein combustions, reactions and crystal growths take place, a cylindrical side wall 21, a cover disc 22 and a base disc 23. There is a support element 3 for a seed 9 which acts as a special substrate for the growth of a crystal (it is also conceivable to place a certain number of seeds side by side); the element 3 is mounted to a rod 4 which can rotate and translate upward and downward, thereby rotating and translating the element 3, the seed 9 and the growing crystal. At the bottom, the chamber 2 has a cylindrical inner wall 24 parallel to the outer cylindrical side wall 21. A porous element 51 is mounted high to the wall 24 at the centre, and a porous element 71 is mounted high between the wall 21 and the wall 24; thus a cylindrical chamber 50 and an annular chamber 70 are defined; the chamber 50 is connected to a duct 52 for the intake of reaction gasses and combustion gasses, while the chamber 70 is connected to four or six ducts 72 for the intake of isolation and/or purge gasses. At the upper end of the reactor 1, on top of the disc 22, there is a gas exhaust system 6 comprising a chamber 60 communicating with the chamber 20 through four or six holes 61 obtained in the disc 22 and having an exhaust duct 62 also communicating with the chamber 60. FIG. 1 does not show any combustion triggering device (although present); this may be, for example, of the electrically or piezoelectrically generated spark type; one or several of these devices must be so positioned that the sparks are formed between the upper surface of the porous elements, where the combustion gasses come out, and the lower surface of the support, but preferably closer to the porous elements.

The reactor of FIG. 1 can be considered to be a system for chemical deposition from the vapour phase, and essentially comprises two components:
a gas diffuser-premixer (50, 51), diversely shaped, which hereafter will always be referred to as burner, since it is responsible for feeding the reagents to the flame;
a seed support (3) capable of supporting first a seed (9) (acting as a special growth substrate) and then a growing crystal. The seed support (3) is advantageously located in front of the burner. The seed support (3) can advantageously be kept in rotation and/or moved back (i.e. away from the burner and the flame) as the crystal grows, in order to improve the uniformity of the crystal growth.

The flame develops in the volume comprised between these two components, i.e. the burner and the seed support, and the heat generated by it is sufficient to heat the seed (9) to the desired process temperature and to turn the reagents or reaction gasses into the actual deposition precursors, i.e. those chemical species which, being adsorbed on the growth surface, cause the growth of the volume of the crystal itself, with an orientation determined by the orientation of the seed used, as in all epitaxial growth processes. The dimensions of the burner (51) and of the seed support (3) are similar or possibly identical, although configurations are to be preferred wherein the diameter of the support (3) is slightly greater than that of the burner (51), so as to stabilize the flame and prevent well-known flame instability phenomena (“flame flickering”) from occurring. The system may be realized either with the seed support located over the burner, which is the most common configuration for flame systems, or with inverted positions, i.e. with the seed support located underneath the burner. The distance between the burner (51) and the seed (9) placed on the support (3) (initially) and the crystal growth surface (afterward) is preferably comprised between 1 cm and 3 cm; if the support (3) is adapted to move back as the crystal grows, said distance may be kept sufficiently constant. The distance separating these two components, i.e. the burner and the seed support, may be used during the growth also to modulate the flame temperature (by acting on reflection), even though better adjustment possibilities are obtained by varying the feed rates of the flame precursors or combustion gasses, e.g. H₂ and Cl₂, as well as of any dilution gasses, such as helium [He] and argon [Ar] and even hydrogen [H].

In general, various movements may be provided for the seed support (3), for example a rotation (around e.g. its own axis of symmetry), a revolution, a translation along a first of three basic directions, a translation along a second of three basic directions, a translation along a third of three basic directions, or a combination of one or more of these.

In the embodiment of FIG. 1, the seed support 3, as well as the surface of the seed 9 and the growing crystal, is substantially parallel to the burner, specifically the surface of the porous elements 51 and 71. Alternatively, they may be inclined between each other at a fixed or variable angle. Anyway, in both cases, the resulting flame is directed toward the surface of the seed and of the growing crystal.

The reaction chamber containing said two elements, i.e. the burner and the seed support, inside is provided with an exhaust system (6) for eliminating the exhausted reaction gasses. Of course, the dimensions of the chamber depend on those of the crystal to be grown. In terms of radius, one may consider a diameter of the inside (20) of the reaction chamber (2) being approximately twice as much as the diameter of the support (3), since the inside (20) of the reaction chamber (2) must be significantly larger than the burner (51) and the support (3); in fact, the reaction chamber (2) does not play an active role in the process.

Although, according to the present invention, the heat required for the reaction is generated inside the reaction chamber typically by combustion through an internal burner, it can not be excluded that other heating means may be provided in the reactor adapted to heat, preferably in a selective and controlled way, the walls of the reaction chamber and/or the seed support. Said heating means may be either resistance type or induction type.

As already mentioned, the burner, in particular its porous elements (51, 71, 81), may be provided with cooling means. Anyway, other cooling means may be provided in the reactor adapted to cool, preferably in a selective and controlled way, the walls of the reaction chamber and/or the seed support. Said cooling means may be liquid circulation type, in particular water, and/or gas circulation type, in particular hydrogen and/or helium and/or argon or air.

In order to prevent the walls from being soiled, in particular the side walls (21) of the reaction chamber (2), they are advantageously lapped by a flow of inert gas which also prevents them from reaching temperatures incompatible with the material they are made of. In general, for isolation and/or for purge purposes, the reactor according the present invention may be provided with means adapted to maintain a gas flow, in particular hydrogen and/or helium and/or argon, substantially adjacent to the internal side of the walls (21) of the reaction chamber (2) at least during the growth processes.

To this end, the reactor may include an annular porous element (71) (see both FIG. 1 and FIG. 2) preceded by an annular mixing chamber (70) supplied with e.g. hydrogen and/or helium and/or argon through e.g. four or six ducts (72). Such a system may advantageously be integrated into a burner, as in the illustrated examples.

It is to be noted that a reactor according to the present invention may have an exhaust system much simpler than that shown in FIG. 1; for example, it may consists essentially of an exhaust duct extending vertically and communicating directly with the inside (20) of the reaction chamber (2).

It is also to be noted that a reactor according to the present invention may comprise additional components than those shown in FIG. 1.

A first addition may consist in means for cooling exhaust gasses. This may be located inside (20) the reaction chamber (2) downstream the seed support (3), in particular well above the seed support (3); this could be e.g. in the form of a cooling coil pipe for a cooling liquid (e.g. water) or a cooling gas (e.g. hydrogen and/or helium and/or argon or air).

A second addition may consist in a barrier wall located inside (20) the reaction chamber (2) to be used for heat isolation and/or for gas flows separation. To this purpose, the barrier wall should be preferably located next to the walls, in particular the side walls (21), of the reaction chamber (2); the barrier wall would be particularly effective if located in a zone where the burner is located particularly around the burner; an isolation and/or purge gas flow may be arranged between the barrier wall and the internal side of the walls of the reaction chamber (2) at least during the growth processes. Appropriate means may be provided for supporting the barrier wall.

Depending on the composition of the supply and consequently on the process temperature, it is possible to obtain the growth of high-quality crystals of semiconductor materials on seeds at growth rates comprised between 500 and 1,000 micron/h, being therefore perfectly compatible with ingot production. Although the material of the seed and the material of the crystal are typically the same, it is possible to have different materials, for example a GaN crystal on a SiC seed or a SiC crystal on a Si seed.

### Description of the Burner

The burner may consist of a central disc (51) made of a porous material and possibly one or several concentric rings (81) made of a porous material, whose function is to distribute the process gasses evenly along the radius. The disc (51) and each of these rings (81) surmount a corresponding mixing chamber (50, 80) which is supplied with the gasses to be distributed into the reaction chamber after flowing through the porous medium. Preferably, the disc (51) and/or the rings (81) are run internally by a cooling coil pipe (not shown in any drawing) for a cooling liquid (e.g. water) or a cooling gas (e.g. hydrogen and/or helium and/or argon or air) used for maintaining a temperature fit for avoiding or greatly limiting any chemical reactions within the pores of the porous medium (51, 81), which may result in safety problems and/or pore occlusion.

As an alternative to the porous medium, one may use burners provided with holes (preferably small holes, e.g. capillaries) for accomplishing the desired gas distribution.

A burner is integrated into the low area of the reactor of FIG. 1. A mixture of reaction gasses and combustion gasses e.g. SiH₄, C₃H₈, He or H₂, Cl₂ may flow in the duct 52, whereas He and/or H₂ may flow in the ducts 72.

FIG. 2 shows a burner being alternative to that of FIG. 1, which is integrated into the low area of a reactor similar to that of FIG. 1; there are three mixing chambers 50, 70, 80, one being central and two being annular, separated from one another by two cylindrical walls designated 24 and 25; there are three porous elements 51, 71, 81; there are three groups of ducts 52 (just one in the example of FIG. 2), 72, 82. A mixture of reaction gasses e.g. SiH₄, C₃H₈, He or Ar or H₂ (possibly also Cl₂) may flow in the duct 52, whereas a mixture of combustion gasses e.g. H₂ and Cl₂ (possibly also He or Ar) may flow in the ducts 82, and He and/or H₂ may flow in the ducts 72; in this way, combustion reaction gasses and combustion gasses are typically kept separate till the reaction chamber.

It is to be noted that the structure for the isolation and/or purge gas (consisting of chamber 70 and porous element 71) may be integrated into a burner even if the burner is not integrated into a reactor.

In a reactor according to the present invention, one may use a single (typically) circular burner or two or more concentric burners or two or more separated burners; the distance between the burner and the growth surface (seed or growing crystal) is preferably 1-5 cm depending on the position and direction.

According to the present invention, the burner may be designed and arranged to operate either in natural configuration (flame going up) or in inverted configuration (flame going down). The latter is preferable for growing layers.

### Features of the Invention for the Flame

As already explained, according to the preferred embodiments of the present invention, the heat for the growth is generated by combustion directly inside the reaction chamber; in this case, it is necessary to find a flame compatible with the material to be grown and with the reagents used for said growth.

In a flame compatible with the growth of the semiconductor materials contemplated by the present invention (in particular silicon carbide) the fuel is hydrogen and the oxidant is a halogen. These elements determine the following highly exothermal combustion reaction: H₂+A₂→2 HA where A stands for a generic halogen, in particular fluorine [F] or chlorine [Cl] or bromine [Br] and preferably chlorine [Cl] (due to its relatively low cost, high availability and adequate thermal yield); the following thermal data applies to these combustion reactions:

| flame | enthalpy | adiabatic temperature rise |
|---|---|---|
| H/F | about 65′000 cal/mol | more than 9′000° C. |
| H/Cl | about 22′000 cal/mol | more than 3′000° C. |
| H/Br | about 9′000 cal/mol | more than 1′200° C. |

The temperature rises of these flame can be modulated down (if necessary) by adding a dilution gas, e.g. an inert gasses, such as helium or argon, or a stoichiometric excess of hydrogen.

Flame adiabaticity is preferable and may be obtained through chamber walls made of internally coated or uncoated graphite, or quartz coated externally with a reflecting metallic film (heat losses are substantially due to irradiation), or simply a metal, in particular stainless steel. In any case, a wall water-cooling or air-cooling system may be provided (in FIG. 1, such a system would be typically arranged adjacent to the wall 21 on the outside of the chamber 2).

Compatibility of these flames (in particular the H/Cl flame) with be apparent from the following description of the various reactions for different semiconductor materials.

### Features of the Invention for Sic

According to the present invention, in an autothermal process for growing SiC crystals with a premixed or diffusive flame, the following compounds may be used:
reaction gasses: silane (SiH₄), chlorosilanes (SiHₓCl₄₋ₓ), fluorosilanes, bromosilanes, metallorganic compounds such as organosilanes (in particular methyllsilanes or ethylsilanes) or halogenated organosilanes (in particular methyllchlorosilanes or ethylchlorosilanes), and hydrocarbons (CH₄, C₂H₄, C₂H₂, C₃H₈, C₄H₁₀, . . . );
carrier gasses: H₂ and/or He, and/or Ar
combustion gasses: typically H₂+Cl₂.

If a doped crystal is desired, the following known doping substances and compounds may be added:
n-type dopants: NH₃ and/or N₂
p-type dopants: TMA (i.e. trimethylaluminum) or an aluminium chloride.

The choice of the silicon and carbon precursors, i.e. the reaction gasses, is not extremely critical, since the process temperatures lead directly to the following thermodynamically stable species: Si, SiCl₂, SiC₂, Si₂C, C₂H₂.

Chlorine compounds (e.g. chlorosilanes and chlorinated organosilanes), as silicon precursors, are typically used if chlorine is also used as a combustion gas. Similarly, for example, fluorine compounds are typically used if fluorine is also used as a combustion gas.

The method according to the present invention has been conceived for growing long crystals, but it may nonetheless be applied to the simpler growth of short crystals, i.e. (monocrystalline) layers.

The typical operating condition in the reaction chamber of the reactor according to the present invention is atmospheric pressure (i.e. about 1.0 atm); however, slightly lower pressures (e.g. till about 0.1 atm or in the range of about 0.4-0.8 atm) also fall within the typical scope of the present invention.

### Features of the Invention for Silicon

According to the present invention, in an autothermal process for growing silicon crystals with a premixed or diffusive flame, the following reaction gasses (typically only one) may be used:
silane, chlorosilanes, fluorosilanes, bromosilanes.

The carrier gasses and combustion gasses already mentioned in relation to silicon carbide may be used.

If a doped crystal is desired, known doping substances or compounds may be added.

### Features of the Invention for III-V Compounds

Another important category of materials to which the present invention is applicable is that of III-V compound semiconductor materials; it is preferably applicable to nitrides, in particular gallium nitride or aluminum nitride, and arsenides, in particular gallium arsenide or indium arsenide, and phosphides, in particular gallium phospide or indium phospide.

Besides the simpler binary compounds, also ternary and quaternary III-V compounds are of technological interest, like for example AlGaN, InGaP, AlGaAsP.

The reaction gasses may correspond to those used in HVPE or HCVD processes, i.e. a hydride of group V and a halide of group III, in particular a chloride.

The reaction gasses may correspond to those used in MOVPE or MOCVD processes, i.e a hydride of group V a metallorganic compound of group III, in particular a methylic or ethylic compound. The carrier gasses and combustion gasses already mentioned in relation to silicon carbide may be used.

If a doped crystal is desired, known doping substances or compounds may be added.

### Chemical Reactions

### Silicon

Some possible reactions using different reaction gasses are the following:

SiH₄→Si₍ₛ₎+2H₂ R1)

SiH₂Cl₂→Si₍ₛ₎+2HCl R2)

SiHCl₃+H₂→Si₍ₛ₎+3HCl R3)

SiCl₄+2H₂→Si₍ₛ₎+4HCl R4)

HCl is a natural byproduct of deposition reactions R2, R3, R4 and thus the considered H/Cl flame is fully compatible with these processes.

It is clear that the presence of HCl in deposition reaction R1 can not cause problems as it gives rise to the following reaction:

SiH₄+4−xHCl→SiHₓCl₄₋ₓ+4−xH₂ R5)

that produces the starting materials of the other deposition reactions.

The process temperature typically ranges between 1,000° C. and 1,300° C.; therefore a dilution gas is necessary for the H/Cl flame.

### Silicon Carbide

Some possible reactions using different reaction gasses are the following:

SiH₄+1/2C₂H₂→SiC₍ₛ₎+5/2H₂ R6)

SiH₄+1/3C₃H₈→SiC₍ₛ₎+20/3H₂ R7)

SiHₓCl₄₋ₓ+1/2C₂H₂→SiC₍ₛ₎+4−xHCl+(2x−3)/2H₂ x=0,1,2 R8)

SiHₓCl₄₋ₓ+1/3C₃H₈→SiC₍ₛ₎+4−xHCl+(3x−2)/3H₂ R9)

HCl is a natural byproduct of deposition reactions R8 and R9 and thus the considered H/Cl flame is fully compatible with these processes.

It is clear that the presence of HCl in deposition reactions R6 and R7 can not cause problems as it gives rise to the following reaction:

SiH₄+4−xHCl→SiHₓCl₄₋ₓ+4−xH₂ R5)

that produces the starting materials of the other deposition reactions.

The process temperature typically ranges between 1,800° C. and 2,500° C.; therefore a dilution gas is necessary for the H/Cl flame.

### III-V Compound Semiconductors

For these materials two classes of reactions are to be considered: those used in HVPE or HCVD processes and those used in MOVPE or MOCVD.

In a MOVPE/MOCVD process, usually, the metal-organic compound is used to supply the III-group element, i.e. Ga and Al and In, and the most adopted ones are Ga(CH₃)₃ or Ga(C₂H₅)₃ and their homologue compounds for Al and In. The V-group element, i.e. N, P, As, is supplied through a hydride like NH₃, PH₃, AsH₃.

In a HVPE/VCDV process, instead of using metal-organic compounds, III-group halides are used. Ga and In are low melting point metals (30° C. and 156° C., respectively), while Al melts at 660° C.; thus, particularly for Ga, it is easy to bubble an H₂/HCl stream to produce a gas containing GaCl to be fed to the deposition chamber.

Processes using halides are operated at higher temperatures because of the greater stability of these compounds with respect that of the corresponding metal-organic ones. To report a classic example, the GaN MOCVD/MOVPE process (GaMe₃/NH₃/H₂) is operated at about 650° C., while the corresponding HCVD/HVPE process (GaCl/NH₃/H₂) is operated at about 1,050° C. Nevertheless, the higher temperature produces a higher deposition rate (about 100 micron/h vs 1 micron/h).

Even for these materials, the halogen, e.g. Cl, and the halide, e.g. HCl, (deriving from a hydrogen/halogen flame) do not interfere negatively with the deposition chemistry.

Different process temperatures are associated to these processes; therefore an approprite dilution gas quantity may be necessary for the flame depending on the process to be carried out.

### Gallium Arsenide

### HCVD/HVPE:

Ga(1)+HCl→GaCl+1/2H₂

GaCl+AsH₃→GaAs(s)+HCl+H₂

### MOCVD/MOVPE:

Ga(CH₃)₃+AsH₃→GaAs(s)+3CH₄

### Gallium Phosphide

### HCVD/HVPE:

Ga(1)+HCl→GaCl+1/2H₂

GaCl+PH₃→GaP(s)+HCl+H₂

### MOCVD/MOVPE:

Ga(CH₃)₃+PH₃→GaP(s)+3CH₄

### Gallium Nitride

### HCVD/HVPE:

Ga(1)+HCl→GaCl+1/2H₂

GaCl+NH₃→GaN(s)+HCl+H₂

### MOCVD/MOVPE:

Ga(CH₃)₃+NH₃→GaN(s)+3CH₄

### Indium Phosphide

### HCVD/HVPE:

In(1)+HCl→InCl+1/2H₂

InCl+PH₃→InP(s)+HCl+H₂

### MOCVD/MOVPE:

In(CH₃)₃+PH₃→InP(s)+3CH₄

### Aluminum Nitride

### HCVD/HVPE:

Al(1)+HCl→AlCl+1/2H₂

AlCl+PH₃→AlN(s)+HCl+H₂

### MOCVD/MOVPE:

Al(CH₃)₃+NH₃→AlN(s)+3CH₄

### Tests

For the practical realization of the tests described below a commonly available “McKenna” type burner was used, which is currently manufactured and sold by Holthuis & Associates, Sebastopol, Calif., USA.

It is to be noted that burners based on porous elements are known per se from the patent literature since a long time, for example from U.S. Pat. No. 4,354,823.

### Test 1 on SiC

A quartz chamber containing a porous-element burner (51) like the one shown in FIG. 1 and a support element (3), both having a diameter of 70 mm, were supplied with 1.5 slm of silane, 0.15 slm of n-propane, 1.0 slm of hydrogen and 1.5 slm of chlorine. All these gasses were supplied into the inner compartment (50) of the burner. 0.5 slm of hydrogen were supplied to the outer ring (70) of the burner in order to create the gaseous shield for protecting the walls. The pressure in the growth system was kept at atmospheric level. The flame was lit by means of a piezoelectric device, and the distance between the support (3) and the burner (51) was set to 20 mm. With these feeds, the flame temperature reached 2,100° C. About one hour later, the feeds were interrupted and the deposit on the support element (3) was examined. This deposit was just only polycrystalline silicon carbide, since no growth seed had been placed on the support (3).

### Test 2 on SiC

In a system set up similarly to that of TEST 1, a monocrystalline silicon carbide wafer (9) with 6H orientation was placed on the support (3). After about two hours of growth, a deposit was obtained which maintained the same crystalline orientation as the seed used, with a recorded growth rate of 800 micron/hour.

### Test 3 on SiC

In a system similar to those described above, silane was replaced with trichlorosilane as a silicon precursor in the process gasses. The feed rates used were the following: 1.5 slm of trichlorosilane, 0.15 slm of n-propane, 1.0 slm of hydrogen and 1.5 slm of chlorine. All these gasses were supplied into the inner compartment (50) of the burner. 0.5 slm of hydrogen were supplied to the outer ring (70) of the burner in order to create the gaseous shield for protecting the walls. The pressure in the growth system was kept at atmospheric level. The flame was lit by means of a piezoelectric device, and the distance between the support (3) and the burner (51) was set to 18 mm. After about two hours of growth, a deposit was obtained which maintained the same crystalline orientation as the seed used, with a recorded growth rate of approximately 800 micron/hour.

### Test 4 on SiC

A system similar to those described above was supplied with the following process gasses: 1.5 slm of trichlorosilane, 0.15 slm of n-propane, 0.5 slm of hydrogen and 0.5 slm of chlorine. All these gasses were supplied into the inner compartment (50) of the burner. 1.0 slm of chlorine and 1.0 slm of hydrogen were supplied to the outer ring (70) of the burner in order to create the “thermal lens”, thereby obtaining a flame being more concentrated locally and capable of reaching higher temperatures than in the previous systems. By so doing, the maximum temperature of the system was reached on the outer ring of the burner, while the quantity of HCl being present in the central compartment was reduced. The pressure in the growth system was kept at atmospheric level. The flame was lit by means of a piezoelectric device, and the distance between the support (3) and the burner (51) was set to 18 mm. After about two hours of growth, a deposit was obtained which maintained the same crystalline orientation as the seed used, with a recorded growth rate of approximately 1,000 micron/hour.

### Test 5 on Si

To the apparatus already described, in the inner compartment (50) in order to assure a premixed inlet there was fed an overall gas flow rate of 7.85 standard liters per minute of the following species: trichlorosilane, hydrogen and chlorine. The correspondent molar fractions were 0.191, 0.637 and 0.172. Trichlorosilane was previously vaporized in a bubbler through a suitable stream of hydrogen to produce the above inlet composition. The flame reactor was operated at atmospheric pressure and a flame temperature of 1,120° C. was measured. A silicon wafer was used as a seed (9) for the deposition while the seed support (3) was rotated at 50 rpm. After 2 hours the growth was stopped and a growth rate of 16 micron/min of single-crystalline silicon was measured.

### Test 6 on GaAs

In a bubbler at 600° C., pure gallium is kept in liquid conditions when a stream of 0.6 standard liter per minute of hydrogen containing 16.6% in volume of hydrochloric acid was bubbled in. In these conditions, the hydrochloric acid is fully converted to GaCl that represents the desired deposition precursor. This stream was fed to the reactor together with 5.450 standard liter per minute of hydrogen, 1,800 standard liters per minute of chlorine and 4,000 standard liters per minute of arsine. All these gases were fed to the inner compartment (50) to assure a premixed feed. The reactor was operated at atmospheric pressure and a flame temperature of 990° C. was measured. A gallium arsenide wafer was used as a seed (9) for the deposition while the seed support (3) was rotated at 20 rpm. After 2 hours the growth was stopped and a growth rate of about 1 micron/min of single-crystalline gallium arsenide was measured.

### Test 7 on GaN

In a bubbler at 600° C., pure gallium is kept in liquid conditions when a stream of 0.6 standard liter per minute of hydrogen containing 16.6% in volume of hydrochloric acid was bubbled in. In these conditions, the hydrochloric acid is fully converted to GaCl that represents the desired deposition precursor. This stream was fed to the reactor together with 5.250 standard liter per minute of hydrogen, 2,500 standard liters per minute of chlorine and 7,000 standard liters per minute of ammonia. All these gases were fed to the inner compartment (50) to assure a premixed feed. The reactor was operated at atmospheric pressure and a flame temperature of 1,060° C. was measured. A silicon carbide wafer, previously coated with a gallium nitride film, was used as a seed (9) for the deposition while the seed support (3) was rotated at 30 rpm. After 2 hours the growth was stopped and a growth rate of about 56 micron/h of single-crystalline gallium nitride was measured.

### Test 8 on AlN

In a bubbler at 60° C., pure trimethylalluminium is kept in liquid conditions when a stream of 1,000 standard liter per minute of hydrogen is bubbled inside in order to reach saturation conditions for the gas leaving the bubbler. The resulting gas has a trimethylalluminium mole fraction of 0.0786. This stream was fed to the reactor together with an addition of hydrogen, chlorine and ammonia to produce an overall flow rate of 6,000 standard liter per minute. All these gases were fed to the inner compartment (50) to assure a premixed feed. The resulting inlet composition was 0.0054, 0.3850, 0.2246 and 0.3850 for trimethyl alluminium, hydrogen, chlorine and ammonia, respectively. The reactor was operated at atmospheric pressure and a flame temperature of 1,450° C. was measured. A silicon carbide wafer, previously coated with alluminium nitride film, was used as a seed (9) for the deposition while the seed support (9) was rotated at 20 rpm. After 2 hours the growth was stopped and a growth rate of about 30 micron/h of single-crystalline aluminum nitride was measured.

1. Method for growing a crystal of a semiconductor material on a seed placed on support means located inside a reaction chamber, comprising the steps of:
introducing, preferably in a continuous way, at least one reaction gas into the reaction chamber having a wall, said at least one reaction gas being such as to react if heated, preferably at high temperature, and to generate said material;
introducing, preferably in a continuous way, combustion gasses into the reaction chamber;
triggering combustion between said combustion gasses; and
depositing said generated material on said seed.

2. Method according to claim 1, wherein said combustion gasses are hydrogen and a halogen.

3. Method according to claim 2, wherein said combustion gasses are hydrogen and chlorine.

4. Method according to claim 1, wherein said at least one reaction gas and said combustion gasses are mixed before being introduced into said reaction chamber.

5. Method according to claim 1, wherein said at least one reaction gas is mixed with a carrier gas, including hydrogen, helium, helium, and/or argon.

6. Method according to claim 1, wherein said combustion gases are mixed with a dilution gas, including hydrogen, helium, and/or argon.

7. Method according to claim 1, wherein the introduction of said at least one reaction gas and said combustion gasses is carried out by means of a porous element.

8. Method according to claim 1, wherein the combustion is arranged so that a flame is generated.

9. Method according to claim 8, wherein said flame is directed toward the surface of said seed.

10. Method according to claim 1 further comprising: a gas flow is arranged substantially adjacent to an internal side of the walls of said reaction chamber at least during the growth processes.

11. Method according to claim 1, wherein said material is silicon carbide.

12. Method according to claim 1, wherein said material is silicon carbide.

13. Method according to claim 1, wherein said material is a III-V compound semiconductor material.

14. (canceled)

15. (canceled)

16. (canceled)

17. (canceled)

18. (canceled)

19. A reactor for growing crystals of a semiconductor material on seeds comprising:
a reaction chamber having an internal wall;
support means for at least one seed;
inlet means for at least one reaction gas;
inlet means for combustion gasses; and
trigger means for triggering combustion between said combustion gasses.

20. A reactor according to claim 19, further comprising a burner for said combustion gasses, said burner being located inside said reaction chamber in front of said support means.

21. (canceled)

22. A reactor according to claim 20, wherein said burner comprises at least one mixing chamber.

23. A reactor according to claim 19, further comprising a first mixing chamber for reaction gasses and combustion gasses.

24. (canceled)

25. (canceled)

26. Reactor according to claim 19, further comprising a means adapted to cool the walls of said reaction chamber.

27. (canceled)

28. A reactor according to claim 19, wherein said support means are adapted to rotate.

29. Reactor according to claim 19, further comprising a means adapted to maintain a gas flow substantially adjacent to the internal side of the walls of said reaction chamber.

30. (canceled)

31. (canceled)
